(19) United States
(12) Patent Application Publication
(10) Pub. No.: US 2007/0004058 A1
(43) Pub. Date: Jan. 4, 2007

(54) Semiconductor manufacturing device with transfer robot

(76) Inventors: Heok-Jae Lee, Suwon-si (KR); Sung-Wook Park, Suwon-si (KR); Do-In Bae, Changweon-si (KR); Kee-Weone Seo, Suwon-si (KR); Chang-Woo Woo, Yongin-si (KR); Tae-Won Lee, Seongnam-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/478,578

(22) Filed: Jul. 3, 2006

(30) Foreign Application Priority Data
Jul. 4, 2005 (KR) 2005-59661

(51) Int. Cl. H01L 21/66

(52) U.S. Cl. 438/14

(57) ABSTRACT

Semiconductor manufacturing equipment is disclosed and comprises a robot comprising a robotic arm adapted to transfer a wafer from a wafer cassette in a load lock chamber to a processing chamber with proper alignment and positioning without the need to intermediately pass through a support chamber specially adapted to align and position the wafer.

### BACKGROUND AND SUMMARY

1 . Field of the Invention

Embodiments of the invention relate to semiconductor manufacturing device adapted to transfer a wafer by means of a robot. More particularly, embodiments of the invention relate to a semiconductor manufacturing device adapted for use with a robot and more efficiently adapted to transfer a properly aligned and positioned wafer amongst processing chambers.

A claim of priority is made to Korean Patent Application 10-2005-0059661 filed on Jul. 4, 2005, the subject matter of which is hereby incorporated by reference in its entirety.

2. Description of the Related Arts

The manufacture of semiconductor devices involves an application of a complex sequence of fabrication processes to a substrate (e.g., a silicon wafer) on which the semiconductor devices are to be formed. Common fabrication processes include processes related to photolithography, etching, ion implantation, diffusion, metal deposition, etc.

Various specialized pieces of manufacturing equipment perform the fabrication processes. Thus, it is necessary to physically transfer wafers between the equipment. Given the very real concerns over possible contamination of and/or damage to the wafers, transfer of the wafers is a difficult problem. Each unique piece of fabrication equipment may define a unique position and alignment at which it accepts one or more wafers for processing, or a unique staging position preparatory to processing. Thus, the transfer process must ensure accurate transfer and alignment of wafers as between various pieces of fabrication equipment.

One example of conventional transfer and alignment of wafers will now be described with reference to Figure (FIG. 1). Referring to FIG. 1, semiconductor manufacturing equipment 10 is associated with a semiconductor manufacturing line and adapted to transfer one or more wafers W. The transfer process implemented by semiconductor manufacturing equipment 10 uses load lock chambers La and Lb into which a wafer cassette C may be loaded. Each wafer cassette C may contain a plurality of wafers. Opposing doors D1 and D2 in load lock chambers La and Lb may be selectively opened or closed to allow loading or unloading of a wafer cassette. In the illustrated embodiment, door D2 of load lock chambers La and Lb open into a sealed transfer chamber T. Transfer chamber T is typically a clean environment and is routinely fixed with a robot 12 adapted to transfer wafers W or wafer cassettes C from either one of load lock chambers La and Lb to a desired position.

Transfer chamber T is further adapted to allow transfer of wafers W or wafer cassettes C to any one of a plurality of process chambers (e.g., P1, P2, P3, P4). Respective doors D3 allow loading and unloading of process chambers P1, P2, P3, P4. Further, wafers W or wafer cassettes C may be transferred by means of transfer chamber T and robot 12 to and from a support chamber S. Support chamber S commonly performs a function of consistently aligning the center of a loaded wafer with a set position. This set position may be defined in relation to a wafer flat zone (e.g., a flattened wafer edge).

Within the wafer transferring process performed by the semiconductor manufacturing equipment 10, a wafer cassette C holding a plurality of wafers is held at a predetermined position within either one of load lock chambers La and Lb. Robot 12 transfers wafers from a wafer cassette C using a robot chuck 18 supported on robotic arms 16a and 16b. By means of robotic arms 16a and 16b, robot chuck 18 may be extended into a wafer cassette C to retrieve a wafer W. Once a wafer W is grasped, robotic chuck 18 may be withdrawn by contraction of robotic arms 16a and 16b. Then robot chuck 18 may be rotated to face support chamber S. Control of all aspect of robot 12 are conventionally controlled by various control signals provided by a controller (not shown) operating under a defined software routine and/or a human operator's instruction.

At this point, robot 12 inserts wafer W into support chamber S. Within support chamber S, a sensor (not shown) is used to-detect the wafer flat zone and properly align the wafer in relation to the flat zone.

Once properly aligned, wafer W is extracted from support chamber S by robot 12. Then, robot 12 rotates to face a selected one of the plurality of processing chambers P1, P2, P3 and P4 and loads wafer W therein.

As described above, wafer W is conventionally aligned in support chamber S before being transferred by robot 12 to a selected process chamber. However, the provision of support chamber S adds considerable size to the foot-print of semiconductor manufacturing equipment 10 within the manufacturing facility. Further, the double transfer requirement (i.e., load lock chamber-to-support chamber-to-process chamber) by robot 12 takes overly long and adversely impacts manufacturing productivity.

### SUMMARY OF THE INVENTION

In one embodiment, the invention provides semiconductor manufacturing equipment, comprising; a robot comprising a robotic arm adapted to transfer a wafer from a wafer cassette in a load lock chamber to a processing chamber with proper alignment and positioning without the need to intermediately pass through a support chamber specially adapted to align and position the wafer.

In another embodiment, the invention provides semiconductor manufacturing equipment, comprising; a plurality of processing chambers adapted to receive a wafer from a central transfer chamber via a robotic arm, a load lock camber holding a wafer cassette, the wafer cassette holding a plurality of wafers, a robot contained within the transfer chamber and comprising a robotic arm adapted to transfer one of the plurality of wafers from a wafer cassette from the load lock chamber to one of the plurality of processing chambers with proper alignment and positioning without the need to intermediately pass through a support chamber specially adapted to align and position the wafer.

### BRIEF DESCRIPTION OF THE DRAWINGS

FIG. 1 is a schematic view illustrating conventional semiconductor manufacturing equipment;

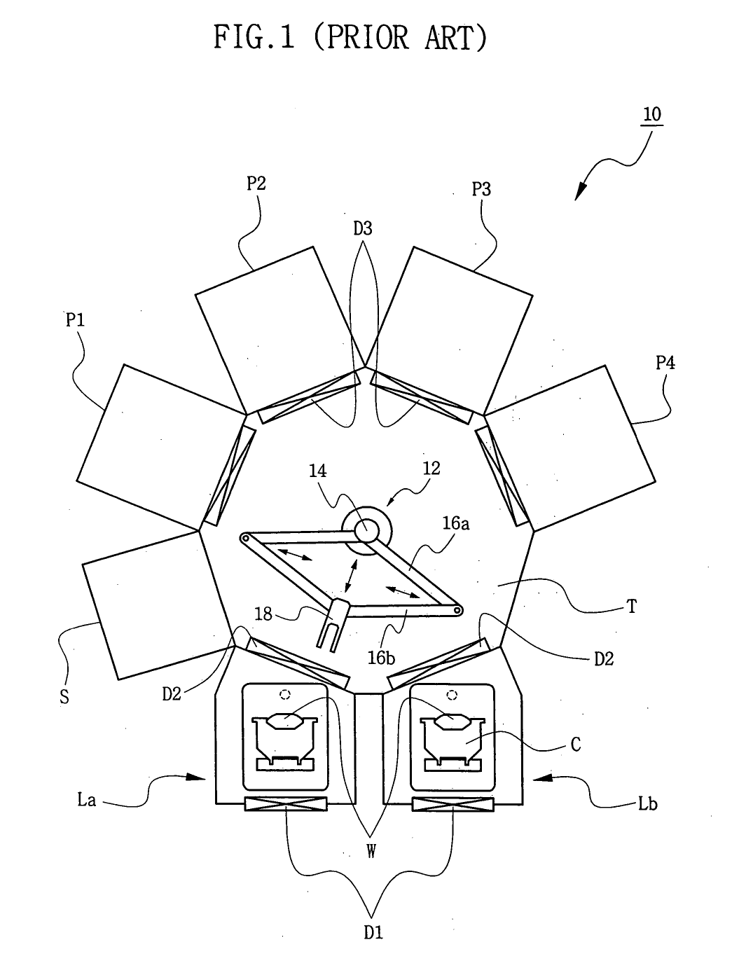

FIG. 2 is a schematic view illustrating a semiconductor manufacturing equipment according to an embodiment of the invention;

FIG. 3 is a cross-sectional view schematically illustrating sensors taken along line I-l′ in FIG. 2; and

FIG. 4 is a perspective view illustrating robot transfer within an embodiment of the invention.

### DESCRIPTION OF EMBODIMENTS

Embodiments of the invention will be described with reference to accompanying drawings. However, the invention is not limited to only the illustrated embodiments but may be variously embodied.

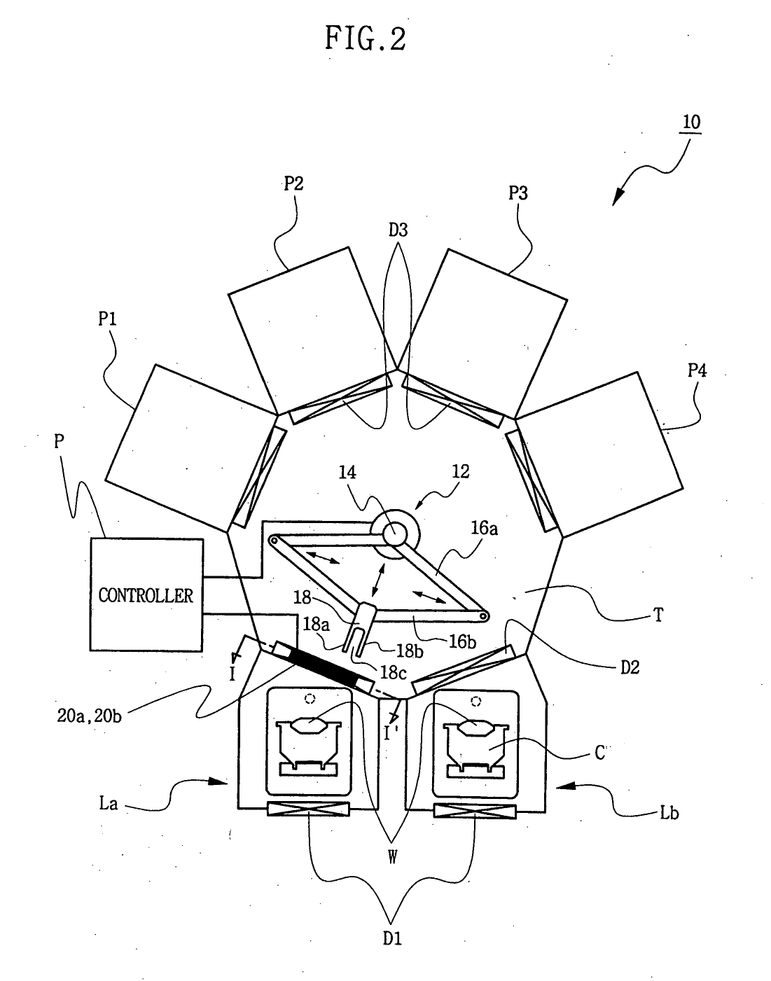

FIG. 2 is a schematic view of semiconductor manufacturing equipment according to an embodiment of the invention. Referring to FIG. 2, the disposition of wafer cassette C holding a plurality of wafers W as loaded within load lock chambers La and Lb, as well as the disposition of load lock chambers La and Lb and processing chambers P1, P2, P3, and P4 to transfer chamber T are similar to the conventional arrangement. Here again, a robot 12 within transfer chamber T transfers wafers W between the various positions discussed above.

However, door D2 associated with load lock chambers La and/or Lb is fitted with sensor components 20a and 20b. In the illustrated embodiment, one sensor component 20a is fitted to an upper portion of door D2 and another sensor component 20b is fitted to a lower portion of door D2. The sensor formed by sensor components 20a and 20b may be an optical sensor, such as an infrared sensor.

As wafer W is unloaded from load lock chamber La or Lb by robot 12 the combination of sensor components 20a and 20b generate an alignment signal indicative of the wafers orientation as grasped by robot 12. For example, a light beam (e.g., infrared energy) may be emitted from a first sensor component 20a (e.g., a photodiode or laser) and received (or not) by a second sensor component 20b. That is, when blocked by wafer W the emitted light does not reach second sensor component 20b. Second sensor 20b (e.g., a photodetector) is adapted to generate the alignment signal and provide to connected controller P (e.g., a PC, laptop or handheld computer). Upon receiving the alignment signal, controller P is able to determine the relative position and alignment of wafer W. For example, controller P may be adapted to detect a center of wafer W in relation to the received alignment signal. Having determined the relative position and alignment of wafer W, controller P is able to control the movement of robot 12.

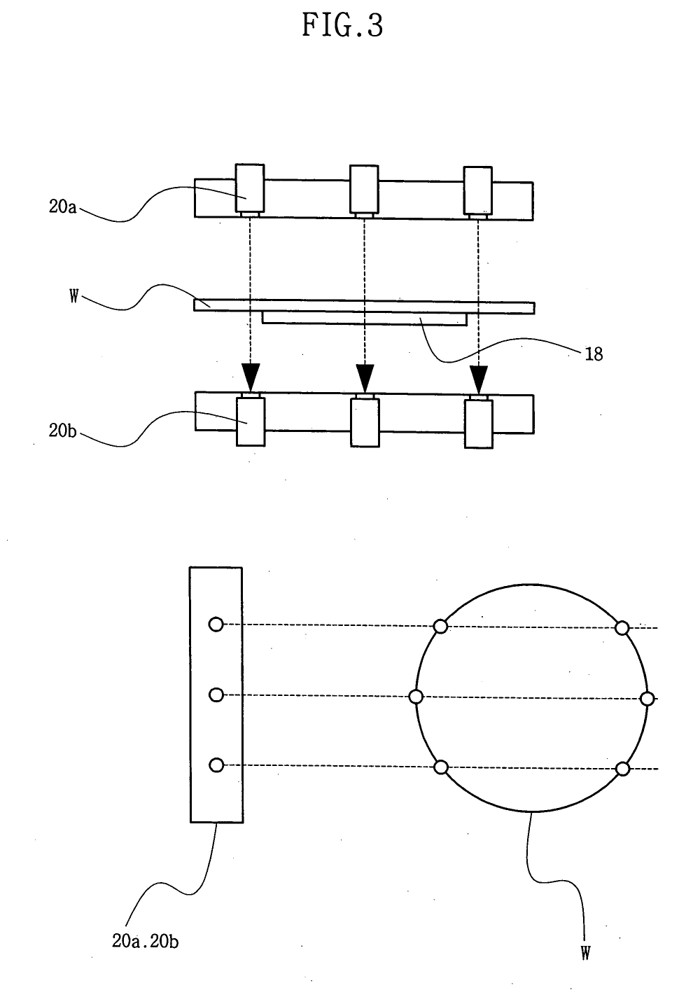

FIG. 3 is a cross-sectional view schematically illustrating sensor components 20a, 20b as positioned along line I-l′ in FIG. 2. Referring to FIG. 3, when robot 12 unloads wafer W from load lock chamber La or Lb into transfer chamber T, light emitted from first sensor component 20a either irradiates second sensor component 20b or is blocked by wafer W. The timed presence and absence of the emitted light at second sensor component 20b, as indicated by the alignment signal provided by second sensor component 20b, allows controller P to determine position and alignment information. Movement of robot 12 may then be made with knowledge of the actual position and alignment information.

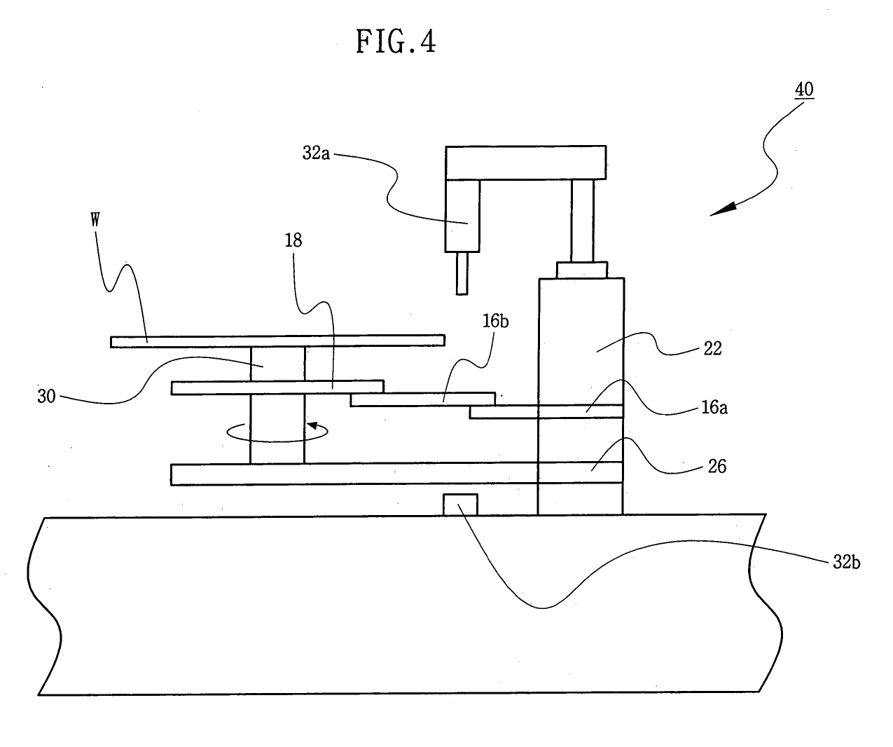

FIG. 4 is a perspective view further illustrating a robot adapted for use in the semiconductor manufacturing equipment according to an embodiment of the invention. Referring to FIG. 4, robot 40, as adapted to transfer wafer W, comprises; a first robot arm 16a adapted to rotate around a supporting axis member 22, a second robot arm 16b linked to a vertical hem and adapted to rotate relative to first robot arm 16a; and a robot chuck 18 adapted to support wafer W and connected to second robot arm 16b.

Robot chuck 18 comprises finger parts 18a and 18b bracketing a groove 18c and adapted to support only an edge portion of wafer W to thereby reduce the contact area between wafer W and robot chuck 18.

A guide rail 26 may also be provided as part of robot 40 as a support to a rotating member 30. Guide rail 26 may be connected to supporting axis member 22. As a complete assembly, guide rail 26 and robot chuck 18 may cooperate to move wafer W up, down, and around along the length of guide rail 26. Rotating member 30 may be adapted to fix the under side of wafer W (e.g., with a vacuum pressure) and may be further adapted to fit through groove 18c of robot chuck 18.

If wafer W is rotated by means of rotating member 30 third and fourth sensor components 32a and 32b may readily be used to sense the flat zone position of wafer W.

Additional (third and fourth) sensor components 32a and 32b may be provided with robot 40. Various CCD camera components, photocouplers, etc., may be used to implement these sensor components. However implemented, the additional sensor components may be used to sense the flat zone position of wafer W. In this regard, additional sensors 32a and 32b may be adapted to send a wafer alignment signal to controller P. Here again, controller P, upon receiving the alignment signal from additional sensors 32a and 32b may used this information to position wafer W using robot arm 16a, 16b and rotating member 30.

As illustrated robots 12 and 40 are shown with first and second robot arms that to move in relation to supporting axis member 22. However, a robot of any reasonable construction might be used (e.g., cantilever arms having a plurality of articulations, etc.).

When reviewing processes for transferring and aligning the wafer, robot 40 extends and drives robot arm 18 to seat robot chuck 18 against the bottom side of wafer W when wafer W is placed on any predetermined position. Robot 40 goes up and down, and drives supporting axis 22 so that the wafer is placed on the upper side of robot chuck 18. Accordingly, when wafer W is supported on robot chuck 18, the robot contracts and drives robot arm 18. In the process to unload wafer W from wafer cassette C in load lock chamber La or Lb into transfer chamber T using robot chuck 18, when sensor components 20a, 20b are installed between the load lock chamber La or Lb and transfer chamber T, the position and alignment of wafer W is detected and a corresponding alignment signal is sent to controller P. Then, controller P controls robot 40 to correctly adjust the position and alignment of wafer W.

Thus, a determination of position and alignment for wafer W is made in relation to a predetermined standard position. For example, a distance and direction between the actual position of the center of wafer W and a standard (e.g., properly seated) position of the center of the wafer W may be used to re-position wafer W using robot 40 and controller P.

Re-positioning may be accomplished (and/or verified) using additional sensor components 32a and 32b in conjunction with robot 40, including rotating member 30.

Thus, the process of properly aligning and positioning wafer W is performed entirely without the need for a specialized support chamber S.

Properly positioned and aligned wafers W may be directly provided from load lock chambers La and Lb to any one of the plurality of process chambers P1, P2, P3, P4 using robot 40 and controller P. This approach decreases the foot-print of the semiconductor manufacturing equipment and increases wafer throughput.

It will be apparent to those skilled in the art that modifications and variations can be made in the foregoing without removing such from the scope of the present invention as defined by the following claims.

What is claimed is:

1. Semiconductor manufacturing equipment, comprising:
a robot comprising a robotic arm adapted to transfer a wafer from a wafer cassette in a load lock chamber to a processing chamber with proper alignment and positioning without the need to intermediately pass through a support chamber specially adapted to align and position the wafer.

2. The semiconductor manufacturing equipment of claim 1, wherein the load lock chamber comprises:
a door through which the robotic arm unloads the wafer from the wafer cassette into a transfer chamber;
sensor components adapted to generate an alignment signal indicating an actual alignment and position of the wafer on the robot arm; and,
a controller adapted to re-position the wafer using the robotic arm in response to the alignment signal.

3. The semiconductor manufacturing equipment of claim 2, wherein the robot is entirely contained within the transfer chamber.

4. The semiconductor manufacturing equipment of claim 2, wherein the robot further comprises:
a supporting axis member adapted to support the robotic arm;
a guide rail associated with the robotic arm; and,
a rotating member associated with the guide rail and adapted to receive the wafer from the robotic arm and rotate the wafer.

5. The semiconductor manufacturing equipment of claim 4, wherein the robotic arm comprises two finger parts adapted to contact the wafer and a groove separating the two finger parts, wherein the rotating member is further adapted to pass through the groove to receive the wafer from the robotic arm.

6. The semiconductor manufacturing equipment of claim 4, wherein the robot further comprises additional sensor components adapted to detect an alignment and position of the wafer as received by the robotic arm.

7. Semiconductor manufacturing equipment, comprising:
a plurality of processing chambers adapted to receive a wafer from a central transfer chamber via a robotic arm;
a load lock chamber holding a wafer cassette, the wafer cassette holding a plurality of wafers;
a robot contained within the transfer chamber and comprising a robotic arm adapted to transfer one of the plurality of wafers from a wafer cassette from the load lock chamber to one of the plurality of processing chambers with proper alignment and positioning without the need to intermediately pass through a support chamber specially adapted to align and position the wafer.

8. The semiconductor manufacturing equipment of claim 7, wherein the load lock chamber comprises:
a door through which the robotic arm unloads the wafer from the wafer cassette into a transfer chamber;
sensor components adapted to generate an alignment signal indicating an actual alignment and position of the wafer on the robot arm; and,
a controller adapted to re-position the wafer using the robotic arm in response to the alignment signal.

9. The semiconductor manufacturing equipment of claim 8, wherein the robot is entirely contained within the transfer chamber.

10. The semiconductor manufacturing equipment of claim 8, wherein the robot further comprises:
a supporting axis member adapted to support the robotic arm;
a guide rail associated with the robotic arm; and,
a rotating member associated with the guide rail and adapted to receive the wafer from the robotic arm and rotate the wafer.

11. The semiconductor manufacturing equipment of claim 10, wherein the robotic arm comprises two finger parts adapted to contact the wafer and a groove separating the two finger parts, wherein the rotating member is further adapted to pass through the groove to receive the wafer from the robotic arm.

12. A transfer robot comprising:
a robotic arm adapted to transfer a wafer;
a supporting axis member adapted to support the robotic arm;
a guide rail associated with the robotic arm;
a rotating member associated with the guide rail and adapted to receive the wafer from the robotic arm and rotate the wafer;
a sensor components adapted to detect an alignment and position of the wafer as received by the robotic arm; and
a controller adapted to re-position the wafer using the robotic arm in response to the detected alignment and position.

13. The transfer robot of claim 12, wherein the robotic arm comprises two finger parts adapted to contact the wafer and a groove separating the two finger parts, wherein the rotating member is further adapted to pass through the groove to receive the wafer from the robotic arm.
